(19) United States
(12) Patent Application Publication
(10) Pub. No.: US 2009/0293940 A1
(43) Pub. Date: Dec. 3, 2009

(54) Combination solar collector

(76) Inventor: Timothy Sharpe, Freehold, NJ (US)

Correspondence Address: Timothy E. Sharpe, 133 Koster Drive, Freehold, NJ, 07728, US

(21) Appl. No.: 12/454,856

(22) Filed: May 27, 2009

Related U.S. Application Data
(60) Provisional application No. 61/128,900, filed on May 27, 2008.

(51) Int. Cl. H01L 31/058; H01L 31/042

(52) U.S. Cl. 136/248; 136/244

(57) ABSTRACT

This invention describes a combination photovoltaic (PV) and thermal heat collector solar panel that both generates electricity and provides residual heat energy to a transfer medium. The panel is comprised of PV panel material also used as the thermal absorber. The sun-facing surface of the combination absorber generates DC current and directly beneath this is a thermal heat collection system comprised of tubular passages for flow of the heat absorbing fluid (such as water) there through. The panel may have one or more thermal insulating clear cover(s) spaced above the absorber and thermal insulation underneath the absorber plate. The collector may be a flat plate collector or a concentrating type collector with a combination absorber at the focal point and may have a single or dual axis solar tracking system.

### CROSS REFERENCES

Provisional Application No. 61/128,900 filed May 27, 2008, same title, three previous U.S. Pat. Nos. 4,360,005—dated Nov. 23, 1982, 4,483,321—dated Nov. 20, 1984 and 4,485,804—dated Dec. 4, 1984

### FEDERALLY SPONSORED RESEARCH

Not Applicable.

### REFERENCE TO A SEQUENCE LISTING

Not Applicable.

### BACKGROUND OF THE INVENTION

Solar heat collectors are well known in the patent art and have received renewed interest recently due to concerns over climate change and increasing energy costs. Early systems were primarily designed and used for thermal heating of a fluid. This type collector is used for domestic or commercial hot water, heating storage tanks used for space heating, for heating pools and hot tubs, or other commercial heating needs like chemical baths. These systems typically range from less than 30% to up to 90% efficient depending on conditions as measured in accordance with American Society of Heating, Refrigeration and Air-Conditioning Engineers (ASHRAE) Standard 77-2003. More recently the focus has been on photovoltaic (PV) systems for the generation of electricity as new materials and production methods are being developed to increase performance and/or reduce costs.

Since current PV panels are typically only about 6% to 15% efficient, and since they operate more efficiently at lower temperatures, the combination of these two systems has multiple benefits. Current PV panels are typically rated at 25° C., which is about 2° C. above room temperature. Clearly these panels reach temperatures much higher than this when operating in direct sunlight in the summertime. Combining these two collector types improves performance of the PV portion of the collector and also provides considerable direct thermal energy for use, thereby collecting considerably more of the total energy available per square foot of collector.

The inventor has previously patented thin film plastic collectors for heating a transfer medium like water to collect thermal energy. (U.S. Pat. Nos. 4,485,804, 4,483,321 and 4,360,005) Recent advances in depositing photovoltaic (PV) materials on thin film plastics for the collection or production of electricity from solar energy make this combination possible and desirable. The fact that cooling the PV panel actually improves its efficiency is an added benefit.

### BRIEF SUMMARY OF THE INVENTION

This invention describes an improved solar heat collector panel having a combination photovoltaic (PV) and thermal heat absorber that both generates electricity and provides residual heat energy to a transfer medium. The combination absorber is covered with photovoltaic (PV) material and contains passages, fillable with a heat absorbing fluid and built into a single unit. The top or sun-facing surface of the PV absorber generates DC current from direct solar radiation. Directly underneath this and thermally connected to it is a thermal heat collection system comprised of tubular passages for flow of heat absorbing fluid there through. These passages are connected to headers to carry the fluid to and from the panels.

The uncovered combination panel permits the collection of all the readily available photovoltaic energy plus the remaining available thermal energy. PV panels often operate much hotter than their typical 25° C. rating, which reduces operating voltage and power produced. Removing the thermal energy for external use will improve the PV performance.

The panel may have thermal insulating clear cover(s) spaced above the absorber and accordingly may have thermal insulation underneath the absorber plate and around the outside edges. The combination collector will require energy collection, flow, control and storage systems for both thermal and electrical energy. The collector may be a flat plate type solar collector or a concentrating type collector with a dual-purpose absorber at the focal point and may be used with a single or dual axis solar tracking system.

### DESCRIPTION OF THE DRAWINGS

FIG. 1 shows the typical Hottel-Whillier thermal performance curve of an uncovered panel similar to FIG. 2 compared to a panel with a single cover plate. The vertical axis shows panel thermal efficiency η_{g}, which is defined as the actual useful energy collected, divided by the solar energy intercepted by the collector gross area. The thermal efficiency of a nonconcentrating collector is given by equation (8.4) of ASHRAE Standard 77-2003.

FIG. 2 shows the edge view of a typical uncovered combination flat plate panel with optional rear side insulation. This shows the location of the PV material, the tubular passages and the headers of the thermal absorption portion of the panel. Notice that the means for transferring the electrical and thermal energy are not shown.

FIG. 3 shows a cross sectional view through the panel of FIG. 2 along lines A-A. The PV material is clearly shown in direct thermal contact with the absorber tubular passages, which collect and transport the thermal energy from the panel.

FIG. 4 shows the headers and pipes used as transfer means for the fluid and attached wires for collecting and transporting the electricity for external use. Any potential clear covers and insulation around the edges are not shown.

FIG. 5 shows a concentrating collector with a Fresnel lens focusing light on the combination absorber. The fluid passages are shown but piping and wire for thermal and electrical connection means are not shown. These can be used as fixed, single or dual axis-tracking collectors.

FIG. 6 shows a concentrating collector with a parabolic reflector focusing light on the combination absorber. These can also be used as fixed, single or dual axis-tracking collectors.

FIG. 7 shows a concentrating collector with multiple parabolic trough reflectors mounted in a single enclosure, each focusing light on its combination absorber. These reflectors can be connected to a single axis-tracking system to collect the maximum available sunlight and the enclosure could be used to track the other axis. The upper plumbing header is shown and the top of the reflectors can be seen as though the top of the enclosure were transparent.

### DETAILED DESCRIPTION OF THE INVENTION

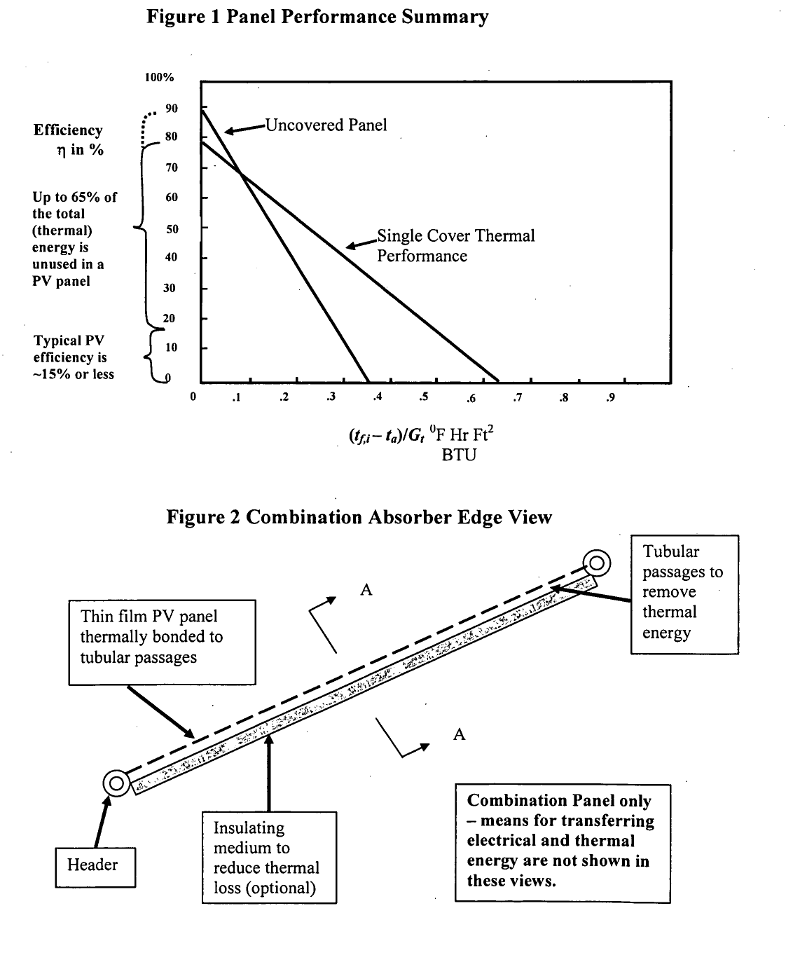

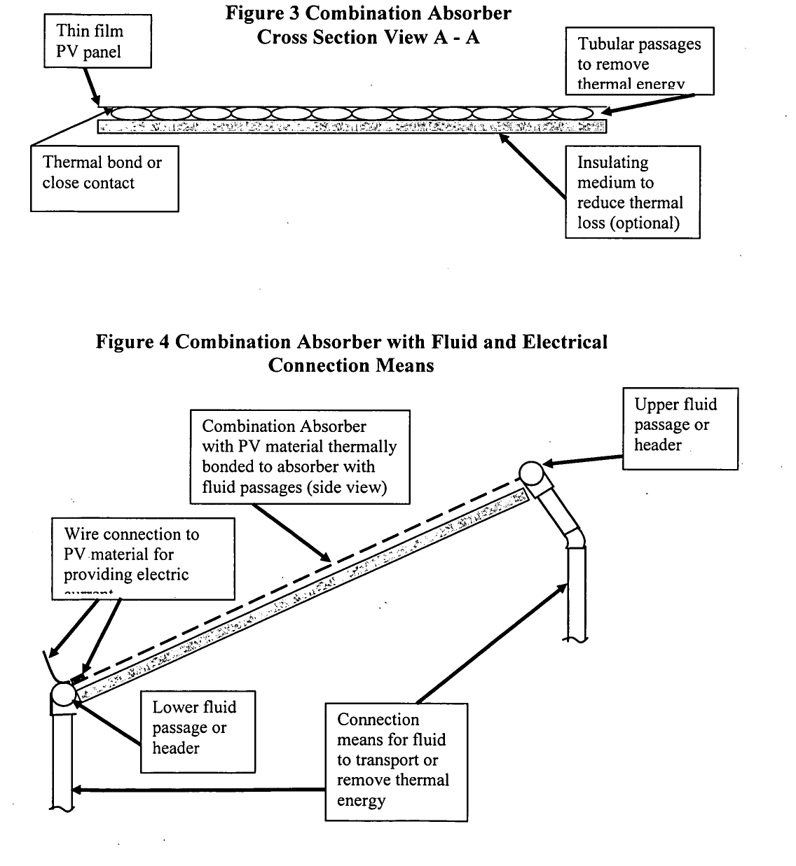

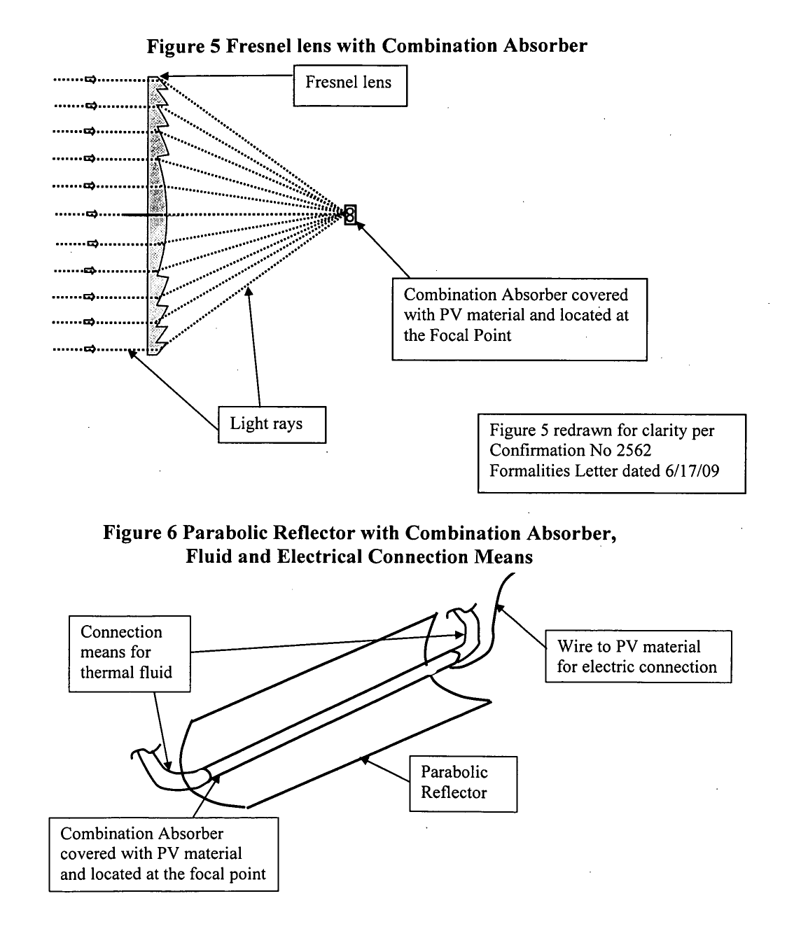

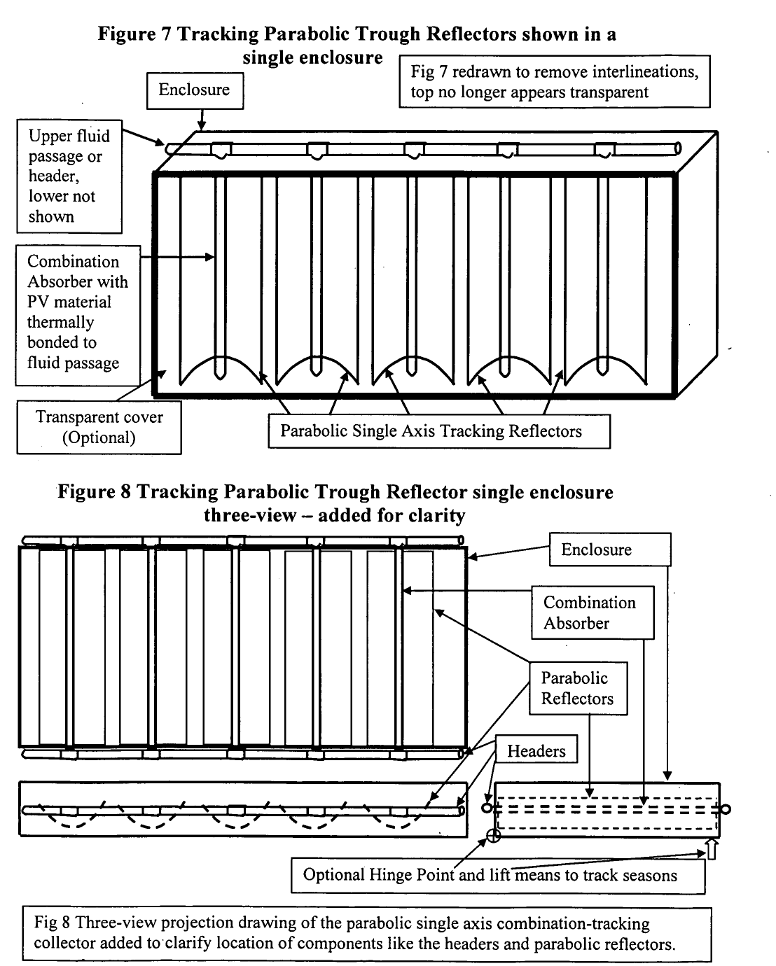

This invention describes a combination photovoltaic (PV) and thermal heat collector that both generates electricity and provides residual heat energy to a transfer medium. The combination collector is comprised of PV material used as the absorber plate of a solar heat collector and built into a single unit. The top or sun-facing surface of the PV absorber generates DC current from direct solar radiation. Directly underneath this and thermally connected to it is a thermal heat absorber generally comprised of a plurality of tubular passages for flow of the heat absorbing fluid (such as water) there through. These passages are connected to headers to carry the fluid to and from the collector. FIG. 1 shows the relative thermal performance of a covered and an uncovered solar panel, where the vertical axis shows panel thermal efficiency η_{g}, The thermal efficiency of a nonconcentrating collector is given by equation (8.4) of the American Society of Heating, Refrigeration and Air-Conditioning Engineers (ASHRAE) Standard 77-2003 as: η_{g}=(Aₐ/A_{g})F_{R}[(τα)ₑ−U_{L}(t_{f,i}−tₐ)/Gₜ].

Where Aₐ is the transparent frontal area and A_{g} is the gross collector area, both in ft². F_{R} is the solar collector heat removal factor and (τα)ₑ is the effective transmittance-absorbance product, both dimensionless. U_{L} is the solar collector heat transfer loss coefficient in Btu/(h*ft²*° F.), t_{f,i} is temperature of the heat transfer fluid entering the collector and tₐ is the ambient air temperature both in F° F. Gₜ is the global solar irradiance incident upon the aperture plane of collector in Btu/h*ft².

When the equation above for a nonconcentrating collector is plotted for efficiency η_{g}, against (t_{f,i}−tₐ)/Gₜ, a straight line will result provided U_{L} is constant. The slope is equal to (Aₐ/A_{g})F_{R}U_{L} and the y intercept is equal to (Aₐ/A_{g})F_{R}(τα)ₑ. In reality, U_{L} is not always a constant but may be a function of the temperature of the collector absorber plate and of the ambient weather conditions, but this approximation is suitable for the discussion here. In FIG. 1 the vertical axis shows panel efficiency ‘η’ and the horizontal axis shows thermal loss expressed as a ratio of temperature of the panel inlet fluid (which is near the collector plate temperature, depending on flow rate) minus the ambient temperature divided by the global solar irradiance all in English units. As the ambient temperature increases or the solar insolation increases the absorbed thermal energy increases and thermal efficiency improves. The bottom of the vertical axis also shows the typical efficiency of a photovoltaic solar panel, which is providing electrical current from the PV material on the combination absorber.

Notice the first 10 to 20% of available energy in this design is captured as PV or electrical energy. The uncovered combination panel permits the collection of all the readily available photovoltaic energy (˜15%) plus the remaining 60 to 70+% of the available thermal energy. The uncovered panel is most efficient thermally when operated at or below the ambient temperature for heating low temperature bodies like swimming pools. The uncovered panel can also be used for heat rejection, particularly at night.

The manufacturing processes for the best thin film PV collectors are carefully guarded and this document covers the combination of presently manufactured or future thin film PV panels with a solar thermal heat collection panel in direct thermal contact with the back of the PV absorber forming a combination absorber. This thermal heat collection panel can be similar to those described in the previously referenced patents and would generally be comprised of a plurality of tubular passages for flow of the heat absorbing fluid (such as water) there through. These would generally be low profile passages of a circular, rectangular or oval-shaped cross-section, preferably parallel or serpentine and thermally integrated with or directly thermally bonded to the back of the PV absorber through manufacturing, adhesive, thermal bonding or other means. Each passage is connected to headers to carry the fluid to and from the panels. The fluid passages should be capable of withstanding the working pressures as determined by the application. The bottom of FIG. 1 shows the optional thermal insulation material to reduce thermal losses. The headers, transfer means for fluid and electricity are shown in FIG. 4, any potential clear covers and insulation around the edges are not shown. Although such fluid could be either a gas or liquid, liquids are preferred in most applications because of their higher specific heat.

The absorber is covered with dark colored PV material which is in direct thermal contact or bonded to the thermal absorber and may be made of either rigid or flexible construction and can be either a flat plate panel or some form of concentrator type collector and can be either fixed or designed to track the sun. Numerous PV materials are being used to generate electricity and suitable materials for the absorber plates are metals and plastics, with plastics typically being lower in cost but more sensitive to high temperature.

The solar collector configuration is arranged so the sunlight entering the panel comes to the PV material first and directly behind it is the thermal absorber. The system may be arranged to prevent undesired loss of heat from the absorber panel to the atmosphere during the heat absorption mode. This is accomplished by providing a cover sheet substantially transparent to solar energy and spaced over the absorber plate element, which provides a “dead air” thermal insulation space, which thereby increases the thermal efficiency of the panel. The insulation space can be increased to improve thermal insulation during the heat absorption mode and decreased during the inactive or stagnant operating mode to improve its heat dissipation characteristics.

Suitable thermal insulation may also be provided on the rear or shade side of the absorber plate to prevent undesirable heat loss from that side of the panel. Such rear side insulation should have a suitably high R value, such as R-3 to R-15, and can be made either rigid or flexible. The rear side insulation and the front cover can be provided by an inflatable plastic member. By using flexible materials for the three main components, the dual purpose absorber, the cover and the insulation, the entire heat absorbing panel assembly can be made flexible. This would facilitate much easier storage and reduce shipping costs.

As is known in the solar PV panel field the PV material is more efficient at cooler temperatures and panel performance is typically rated at 25 degrees centigrade which is just above room temperature. Solar PV panels in direct sunlight can easily reach temperatures much higher than this. By removing this heat with the thermal absorption portion of the system the PV portion will operate more efficiently and this cooling will also extend its useful life.

Although any fluid may be used for heat absorption in the panel passages, the fluid is preferably a liquid instead of a gas due to the higher specific heat of liquids and their increased effectiveness as heat transfer and storage media. Any conveniently available low viscosity liquid can be used, such as water, solutions of water with chemicals such as ethylene glycol, or eutectic salts, with the preferred liquids being water and water-based solutions. For panel uses in applications whenever temperatures below the freezing point of water (32° F.) are encountered and the panel system remains filled at all times, liquid solutions having freezing temperatures below 32° F. should be used, such as water-ethylene glycol solutions. As an alternative, the system can drain down the water to a thermally protected area that doesn't freeze when the panel is inactive or experiencing severe cold temperatures.

The useful orientation of the combination solar collector panel of this invention can range from generally horizontal to vertical, with the upper side being directed toward the sun. The preferred panel orientation is at an angle from the horizontal plane within 15 degrees of the location latitude, so as to be generally perpendicular to direct solar radiation. This heat absorbing panel can also be oriented so as to receive indirect or diffuse radiation, or reflected radiation; however, under these situations the panel performance may be somewhat reduced.

Uses for the solar heating aspect of this panel include heating domestic hot water, heating building spaces, heating swimming pools, health spas and hot tubs, or also as a heat collection and rejection panel used in combination with storage and a heat pump system for fluid or space heating or cooling applications. Although the panel is preferably made flexible for ease in shipping and installation, the absorber plate can be made both rigid and flat or have some particular desired shape such as formed or curved. For rigid panels, rigid plastic materials or metals such as aluminum, copper or steel can be used. Also, although this combination solar collector can be produced in a wide variety of sizes and shapes, rectangular panels having dimensions of 2-4 feet wide by 6-10 feet long are usually preferred for most applications.

An additional advantage of this invention if plastic materials are used in the absorber is that they will not corrode, collect scale or discolor either the liquids used or the mounting surfaces. These plastics are impervious to many chemicals such as acidic or caustic baths, used widely in industry, making the combination solar collector adaptable to heating such industrial and chemical baths.

The combination panel can be operated with one or more clear insulating cover panel(s) and with thermal insulation behind the panel. The addition of each cover reduces the total available energy at the absorber plate (and the PV energy collected) by 5 to 10%, depending on transmittance and reflectivity of the cover, but it has a significant positive effect in reducing thermal losses as shown in FIG. 1. The addition of insulating material behind the panel would have no effect on the PV operation but would further reduce thermal loss and improve thermal efficiency of the panel system.

As stated, PV panels often operate much hotter than their typical 25° C. rating, which reduces operating voltage and power produced. Removing the thermal energy for external use and thereby cooling the combination absorber can improve the PV power generated (up to 0.5% per degree C.).

The PV portion of the panel provides direct current and could be used to power nearly any electrical device. The PV portion is part of a system (not shown) comprised of wires to collect the current, some load device to utilize the current and many options such as storage batteries, measuring equipment, switching equipment, converters or inverters to use this energy for powering household items and interface equipment to connect the system to the commercial electrical grid and receive payment or credit for providing energy to the public utilities through a process called net metering.

The total available thermal energy will be lower on a combined panel than a straight thermal panel as the surface of the absorber is PV material generating electrical energy which comes from the same total solar insolation received, but the total energy collected is considerably more than a PV panel alone. Additionally the two different types of energy can meet complimentary needs without losses from conversion, for example direct domestic hot water, pool or hot tub heating without using burners or electric heating elements. Also on a pool system, the PV energy could be used to run pumps, controls, lighting and other devices. In most cases the PV energy can be used to provide light and power to operate the system, collect and distribute the thermal energy and provide additional electrical energy to operate other appliances, store in batteries for later use or provide to the public utility.

These combination panels can also be incorporated into or designed to look like roof shingles or integrated into a metal type roof systems. There are numerous construction materials and configurations, but the PV material is on the side facing the sun (normally the top) and the thermal collection portion of the panel is directly beneath.

The system can also be configured like a solar concentrating system with a Fresnel or other lenses, or parabolic or other reflectors focused on the combination PV and thermal absorber collection area. It is more critical to remove the heat in a concentrating type collector so the PV and other collector materials do not overheat.

The thermal energy will require collection and management equipment in the form of pumps, sensors, automated controls, valves, plumbing, and possibly storage tanks, heat exchangers and distribution means. The thermal energy could also be collected in a thermo siphon system where the storage tank is above the panel and gravity is utilized to circulate the fluid.

What I claim is:

1. A solar collector for providing electric current and absorbing and transmitting thermal energy to a fluid comprising:
(a) photovoltaic (PV) material for converting the suns rays into electrical current and deposited directly on or thermally bonded to a thermal absorber forming a combination absorber;
(b) connection means to provide said electrical current for external use;
(c) an absorber with passages for absorbing and transmitting thermal energy to a heat absorbing fluid;
(d) connection means to collect and transfer this heated fluid for external use.

2. The solar collector of claim 1 wherein the collector is a flat plate collector panel.

3. The solar collector of claim 2 wherein the solar panel has thermal insulation attached to the rear side of the absorber plate away from the solar exposure side to improve thermal efficiency.

4. The solar collector of claim 3 wherein the solar panel has a cover sheet substantially transparent to solar radiation covering the combination absorber plate on its solar exposure side, attached to the plate at its periphery, sealed and spaced approximately 1 inch or more above the absorber panel to improve thermal efficiency.

5. The solar collector of claim 4 wherein the solar panel has additional thermal insulation attached around the outside edges of the collector to additionally improve thermal efficiency.

6. The solar collector of claim 4 wherein the solar panel has additional cover sheet(s) substantially transparent to solar radiation covering the combination absorber plate on its solar exposure side, attached to the plate at its periphery, sealed and spaced approximately 1 inch or more above the cover below to improve thermal efficiency

7. The solar collector of claim 1 wherein the collector is a concentrating collector with a Fresnel or other lens in front of the combination absorber to concentrate the suns radiation on to the absorber.

8. The solar collector of claim 7 wherein the lens is attached to the collector at its periphery sealed and spaced 1 inch or more above the absorber to act as a cover improving thermal efficiency.

9. The solar collector of claim 8 wherein the solar collector combination absorber is enclosed and has thermal insulation attached to the rear side of the enclosure away from the solar exposure side to improve thermal efficiency.

10. The solar collector of claim 1 wherein the collector is a concentrating collector with a parabolic reflector located behind the combination absorber and focusing the suns radiation onto the absorber.

11. The solar collector of claim 10 wherein the parabolic reflector also constitutes the back of the solar collector panel and has thermal insulation attached to the rear side of the collector away from the solar exposure side.

12. The solar collector of claim 11 wherein the solar panel has a cover sheet substantially transparent to solar radiation covering the collector on its solar exposure side, attached to the collector at its periphery and spaced at least an 1 inch above the absorber to improve thermal efficiency.

13. The solar collector of claim 10 wherein the parabolic reflector is mounted inside a separate collector enclosure with a combination absorber located at the focal point.

14. The solar collector of claim 13 wherein the parabolic reflector is free to turn and track the sun.

15. The solar collector of claim 14 wherein there are multiple parabolic reflectors located inside a single enclosure and linked to track the sun together on at least one axis.

16. The solar collector of claim 15 wherein the reflectors are parabolic troughs that are linked to track the sun together on one axis.

17. The solar collector of claim 16 wherein the solar parabolic troughs track the sun on one axis and the enclosure tracks the sun on the other axis.

18. The solar collector of claim 5 wherein the collector is mounted on a single or dual axis tracking system so it can track the sun and collect the maximum radiation.

19. The solar collector of claim 9 wherein the collector is mounted on a single or dual axis tracking system so it can track the sun and collect the maximum radiation.

20. The solar collector of claim 13 wherein the collector is mounted on a single or dual axis tracking system so it can track the sun and collect the maximum radiation.
